(19) United States
(12) Patent Application Publication
(10) Pub. No.: US 2025/0194252 A1
(43) Pub. Date: Jun. 12, 2025

(54) DRIVING SUBSTRATE AND PREPARATION METHOD THEREFOR

(71) Applicant: Guangzhou China Star Optoelectronics Semiconductor Display Technology Co., LTd., Guangzhou (CN)

(72) Inventors: Zhihui CAI, Guangzhou (CN); Shimin GE, Guangzhou (CN); Yuhua DONG, Guangzhou (CN)

(73) Assignee: Guangzhou China Star Optoelectronics Semiconductor Display Technology Co., LTd., Guangzhou (CN)

(21) Appl. No.: 18/945,565

(22) Filed: Nov. 13, 2024

(30) Foreign Application Priority Data
Dec. 7, 2023 (CN) 202311679453.7

(51) Int. Cl. H01L 27/12

(52) U.S. Cl. CPC H10D 86/60; H10D 86/0221; H10D 86/423; H10D 86/471

(57) ABSTRACT

A driving substrate and a preparation method therefor are provided. The driving substrate comprises a first thin-film transistor and a second thin-film transistor arranged on the substrate. The first thin-film transistor includes two active layers in parallel, and the second thin-film transistor includes a single active layer.

### CROSS-REFERENCE TO RELATED APPLICATION

The present disclosure claims priority to Chinese Patent Application No. 202311679453.7 filed on Dec. 7, 2023, the content of which is incorporated herein by reference in its entirety.

### TECHNICAL FIELD

The present application relates to the field of display technologies, and in particular to a driving substrate and a preparation method therefor.

### BACKGROUND

With the increasing requirements for high resolution, high definition, fast response, low power consumption and other indicators of display devices, metal oxides, due to their higher mobility and lower leakage current compared to low-temperature polycrystalline silicon, are increasingly being used in liquid crystal displays (LCD), organic light-emitting diode displays (OLED), and other high-end display devices.

However, indium gallium zinc oxide devices as current mainstream products, due to their low mobility, are still difficult to be applied to high-end smart terminal products that require high resolution and definition. Meanwhile, it is easy to cause difficulties in controlling a threshold voltage and a leakage current while satisfying high mobility, that is, off-state characteristics are poor. Therefore, it is difficult to meet different requirements for the devices from various circuit units at the same time.

### SUMMARY

A purpose of the present application is to provide a driving substrate and a preparation method therefor, with the aim of providing a driving substrate that can realize both characteristics of devices while taking into account both mobility and off-state characteristics.

In one aspect, the present disclosure provides a driving substrate including:
a substrate;
a first thin-film transistor including a first active layer, a second active layer, and first source and drain electrodes sequentially stacked along a first direction on the substrate, the first source and drain electrodes including a first source electrode and a first drain electrode spaced apart along a second direction, the first direction being perpendicular to the substrate; and
a second thin-film transistor including a third active layer, a connection layer, and second source and drain electrodes sequentially stacked along the first direction on the substrate, the second source and drain electrodes including a second source electrode and a second drain electrode spaced apart along the second direction, the second direction being parallel to the substrate;
where the connection layer includes a first sub-connection and a second sub-connection spaced apart in the second direction, the first sub-connection is located between the second source electrode and the third active layer, and the second sub-connection is located between the second drain electrode and the third active layer.

In another aspect, the present disclosure provides a preparation method for a driving substrate including:
providing a substrate;
forming an active material layer on the substrate;
patterning the active material layer to form a first active layer, a second active layer located on the first active layer, a third active layer, and a connecting material layer located on the third active layer;
forming a first source electrode and a first drain electrode spaced apart on the second active layer, and forming a second source electrode and a second drain electrode spaced apart on the connecting material layer; and
patterning the connecting material layer to form a first sub-connection and a second sub-connection spaced apart in the second direction, wherein the first sub-connection is located between the second source electrode and the third active layer, and the second sub-connection is located between the second drain electrode and the third active layer.

The present disclosure provides a driving substrate and a preparation method therefor, where the driving substrate includes a thin-film transistor and a second thin-film transistor arranged on a substrate. The first thin-film transistor includes a first gate electrode, a gate insulation layer, a first active layer, a second active layer, and first source and drain electrodes stacked in sequence along a first direction. The first source and drain electrodes include a first source electrode and a first drain electrode spaced apart along a second direction. The second thin-film transistor includes a second gate electrode, the gate insulation layer, a third active layer, a connection layer, and second source and drain electrodes stacked in sequence along the first direction. The second source and drain electrodes includes a second source electrode and a second drain electrode spaced apart along the second direction. Herein, the connection layer includes a first sub-connection and a second sub-connection spaced apart in the second direction, wherein the first sub-connection is located between the second source electrode and the third active layer, and the second sub-connection is located between the second drain electrode and the third active layer. Therefore, the first thin-film transistor includes two active layers in parallel to achieve high mobility, while the second thin-film transistor includes a single active layer, that is, the thickness of the active layer is decreased, so that the concentration of charge carriers is effectively controlled, the threshold voltage is adjustable, and off-state characteristics are improved, and thereby the stability of the device is enhanced. thereby, the two thin-film transistors integrated in the driving substrate have two characteristics, which can meet the requirements of different device characteristics in the circuits.

### BRIEF DESCRIPTION OF THE DRAWINGS

The technical solutions and other beneficial effects of the present disclosure will be apparent through a detailed description of the specific embodiments of the present disclosure in conjunction with the accompanying drawings.

FIG. 1 is a schematic diagram of a structure of a driving substrate according to some embodiments of the present disclosure;

FIG. 2 is a schematic flow chart of a preparation method for a driving substrate according to some embodiments of the present disclosure;

FIGS. 3a to 3d are schematic diagrams of a structure of a driving substrate during preparation according to some embodiments of the present disclosure.

### DETAILED DESCRIPTION

The technical solutions in the embodiments of the present disclosure will be clearly and completely described below with reference to the accompanying drawings in the embodiments of the present disclosure. Apparently, the described embodiments are only some of the embodiments of the present disclosure, but not all of the embodiments. Based on the embodiments in this application, all other embodiments obtained by those skilled in the art without creative efforts shall fall within the scope of protection of this application.

In the description of the present disclosure, it should be understood that the terms “first” and “second” are only used for descriptive purposes and cannot be understood as indicating or implying relative importance or implicitly indicating the number of indicated technical features. Thus, features defined as “first” and “second” may explicitly or implicitly include one or more of the described features. In the description of this application, “plurality” means two or more than two, unless otherwise explicitly and specifically limited.

In the present application, unless otherwise expressly stated and limited, the first feature being “above” or “below” the second feature may include direct contact between the first and second features, or may include contact between the first and second features not directly but through another feature between them. Moreover, the first feature being “above”, “over”, and “on top of” the second feature includes the first feature being directly above and diagonally above the second feature, or simply indicating that the first feature is horizontally higher above the second feature. The first feature is “below”, “under”, and “beneath” the second feature, including the first feature directly below and diagonally below the second feature, or simply indicating that the horizontal height of the first feature is less than the second feature.

The following disclosure provides many different embodiments or examples for implementing the various structures of the present disclosure. To simplify the disclosure of the present disclosure, the components and arrangements of specific examples are described below. Of course, they are only examples and are not intended to limit the present disclosure. In addition, the present disclosure may repeat the reference numbers and/or reference letters in different examples, and this repetition is for the purpose of simplification and clarity and does not in itself indicate the relationship between the various embodiments and/or settings in question. In addition, the present disclosure provides examples of various specific processes and materials, but those of ordinary skill in the art may be aware of the application of other processes and/or the use of other materials.

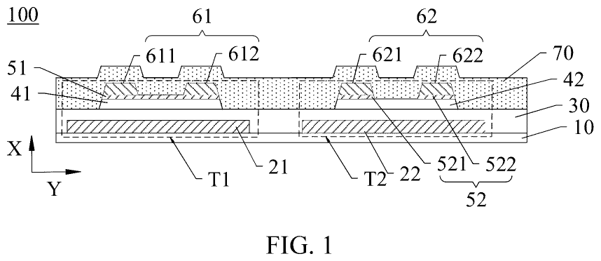

Please refer to FIG. 1, which is a schematic diagram of a structure of a driving substrate according to some embodiments of the present disclosure. The driving substrate 100 can be applied to various displays, such as Liquid Crystal Display (LCD), Organic Light-Emitting Diode (OLED), and Mini-Light-Emitting Diode (Mini-LED), etc.

The driving substrate 100 can further be applied to a variety of electronic devices, such as wearable devices such as smart bracelets, smart watches, augmented reality (AR), virtual reality (VR) and other devices, mobile phones, e-books and newspapers, televisions, personal laptops, flexible displays (foldable, rollable displays and so on) and lighting equipments.

The driving substrate 100 includes a substrate 10, a first thin-film transistor T1 and a second thin-film transistor T2 arranged on the substrate 10. The first thin-film transistor T1 and the second thin-film transistor T2 are spaced apart in a second direction Y. The second direction Y is parallel to the substrate 10, and a first direction X is perpendicular to the substrate 10. The substrate 10 may include one of a glass substrate and a flexible substrate or a combination thereof.

The first thin-film transistor T1 includes a first gate electrode 21, a gate insulation layer 30, a first active layer 41, a second active layer 51, and first source and drain electrodes 61 sequentially stacked along a first direction X on the substrate 10. The first source and drain electrodes 61 include a first source electrode 611 and a first drain electrode 612 spaced apart along the second direction Y. The second thin-film transistor T2 includes a second gate electrode 22, the gate insulation layer 30, a third active layer 42, a connection layer 52, and second source and drain electrodes 62 sequentially stacked along the first direction X on the substrate 10. The second source and drain electrodes 62 include a second source electrode 621 and a second drain electrode 622 spaced apart along the second direction Y.

Herein, the connection layer 52 includes a first sub-connection 521 and a second sub-connection 522 spaced apart in the second direction Y, and the first sub-connection 521 is located between the second source electrode 621 and the third active layer 42. The second sub-connection 522 is located between the second drain electrode 622 and the third active layer 42. Therefore, the first active layer 41 and the second active layer 51 can form a parallel dual channel with high mobility, and the device is not easy to turn on and has high stability. The first sub-connection 521, the third active layer 42, and the second sub-connection 522 can form series-connected single channels with adjustable threshold voltage, relatively small leakage current and good off-state characteristics.

In some embodiments, an orthographic projection of a surface, away from the substrate 10, of the first sub-connection 521 on the substrate 10, coincides with an orthographic projection of a surface, close to the substrate 10, of the second source electrode 621 on the substrate 10. An orthographic projection of a surface, away from the substrate 10, of the second sub-connection 522 on the substrate 10, is coincided with an orthographic projection of a surface, close to the substrate 10, of the second drain electrode 622 on the substrate 10. That is to say, the first sub-connection 521 completely covers the side of the second source electrode 621 facing away from the substrate 10, and the second sub-connection 522 completely covers the side of the second drain electrode 622 facing away from the substrate 10.

In some embodiments, in order to ensure that the middle part of the connecting layer 52 is completely isolated, the patterning process of the connecting layer 52 can be allowed to cause the third active layer 42 to be partially etched, therefore the thickness of part of the third active layer 42 between the second source electrode 621 and the second drain electrode 622 can be smaller than the thickness of the other parts. “Thickness” herein refers to the thickness of the film layer along the second direction Y.

In some embodiments, the first gate electrode 21 may also be arranged on one side of the second active layer 51 away from the substrate 10, and the first gate electrode 21 may be arranged on the same layer on one side of the third active layer 42 departing from the substrate 10.

In some embodiments, the first gate electrode 21 and the second gate electrode 22 are spaced apart on the same layer. The first gate electrode 21 and the second gate electrode 22 are made of a same material, so the first gate electrode 21 and the second gate electrode 22 can be prepared using one mask. The first gate electrode 21 and the second gate electrode 22 may be made of a material including Mo, Mo/Al, Mo/Cu, Mo/Cu/IZO, IZO/Cu/IZO, Mo/Cu/ITO, Ni/Cu/Ni, MoTiNi/Cu/MoTiNi, NiCr/Cu/NiCr, CuNb, etc. The first thin-film transistor T1 and the second thin-film transistor T2 share the gate insulation layer 30. The gate insulation layer 30 may be made of a material including SiOx, SiNx, Al₂O₃/SiNx/SiOx, SiOx/SiNx/SiOx, etc.

The first source and drain electrodes 61 and the second source and drain electrodes 62 may be made of a material including Mo, Al/Mo, Mo/Al/Mo, Mo/Cu, Mo/Cu/IZO, IZO/Cu/IZO, Mo/Cu/ITO,, Ni/Cu/Ni, MoTiNi/Cu/MoTiNi, NiCr/Cu/NiCr, CuNb, etc.

In some embodiments, the first active layer 41 and the third active layer 42 are spaced apart on the same layer, and the second active layer 51 and the connection layer 52 are spaced apart on the same layer.

In some embodiments, the first active layer 41 and the third active layer 42 are made of a same material, and the second active layer 51 and the connection layer 52 are made of a same material. Therefore, the first active layer 41 and the third active layer 42 can be prepared using one mask, and the second active layer 51 and the connection layer 52 can be prepared using one mask.

In some embodiments, the mobility of the first active layer 41 is greater than the mobility of the second active layer 51.

In some embodiments, the first active layer 41 includes a first metal oxide. In one embodiment, the first metal oxide is doped with rare earth element(s), and the doping of the rare earth element can stabilize a threshold voltage. In another embodiment, the first metal oxide can be a crystalline oxide, and the crystalline oxide can further improve mobility.

In some embodiments, the rare earth element includes at least one of ytterbium, europium, praseodymium, terbium, cerium, dysprosium, and tin, and doped with the form of metal oxide(s) thereof. The first metal oxide doped with rare earth elements may include indium gallium zinc oxide, indium zinc oxide, indium gallium oxide, or indium tin zinc oxide. The crystalline oxide may include indium gallium zinc oxide, indium gallium oxide, indium tin zinc oxide, or indium oxide.

In some embodiments, the second active layer 51 includes a second metal oxide. The second metal oxide may be an amorphous oxide, and the amorphous state is beneficial to subsequent patterning and etching processes. The second metal oxide can also be made of indium gallium zinc oxide or gallium zinc oxide. When both the first metal oxide and the second metal oxide are made of indium gallium zinc oxide, the indium content in the first metal oxide is greater than the indium content in the second metal oxide. The high content of indium in the first metal oxide is beneficial for improving the mobility of the channel, and the low content of indium in the second metal oxide is beneficial for controlling the threshold voltage and leakage current.

For example, in the second metal oxide, the ratio of indium, gallium, and zinc is defined as 1:x:y, where x=1 to 5, y=1 to 8. Herein, x can be 1, 2, 3, 4, or 5, and y can be 1, 2, 3, 4, 5, 6, 7, or 8. In the first metal oxide, the ratio of indium, gallium, and zinc is defined as a:b:c, where x=2 to 5, y=0 to 1, z=0 to 1. Herein, a can be 2, 3, 4, or 5, y can be 0 or 1, and z can be 0 or 1.

In some embodiments, the thickness of the first active layer 41 is greater than the thickness of the second active layer 51, the thickness of the third active layer 42 is equal to the thickness of the first active layer 41, and the thickness of the connection layer 52 is equal to the thickness of the second active layer 51. The thickness of the second active layer 51 in the second thin-film transistor T2 is thinner than that of an active layer. Therefore, the thickness of the second active layer 51 and the first active layer 41 can be designed according to the required threshold voltage or off-state characteristics. The smaller thickness of second active layer 51 is beneficial for the thinning and etching process.

In some embodiments, the driving substrate 100 includes a gate driving circuit (such as a GOA circuit), and the gate driving circuit includes the first thin-film transistor T1 and the second thin-film transistor T2. Therefore, for different circuit units in the gate driving circuit, the first thin-film transistor T1 or the second thin-film transistor T2 can be used. For example, for circuit units with high mobility requirements, high stability requirements, and relatively low requirements for off-state characteristics, a first thin-film transistor T1 with two active layers can be used. For devices with relatively high requirements for off-state characteristics and relatively low stability requirements, a second thin-film transistor T2 with a single active layer can be used.

The driving substrate 100 further includes a protective layer 70, and the protective layer 70 covers the first source and drain electrodes 61, the second active layer 51 between the first source electrode 611 and the first drain electrode 612, the second source and drain electrodes 62, and the third active layer 42 between the second source electrode 621 and the second drain electrode 622. That means, the protective layer 70 is directly in contact with the second active layer 51 and the third active layer 42.

The protective layer 70 may include a first protective layer and a second protective layer (not shown) formed in sequence, the first protective layer may be silicon oxide, and the second protective layer may be silicon nitride.

In some embodiments, the first thin-film transistor T1 may include three active layers, that is, the first active layer 41, the second active layer 51, and the fifth active layer (not shown) stacked in sequence. The second thin-film transistor T2 may include a third active layer 42, a connection layer 52, and a sixth active layer (not shown), with the sixth active layer being isolated in the middle as in the connection layer 52, or only the middle of the sixth active layer being isolated.

That is to say, the first thin-film transistor T1 has a structure with multiple active layers, while the second thin-film transistor has a structure with a single active layer, or the number of its active layer is less than the number of active layers of the first thin-film transistor T1. The “number of active layers” mentioned here refers to active layers that are not isolated.

In some embodiments, the total thickness of the first active layer 41 and the second active layer 51 (equivalent to the active layer thickness of the first thin-film transistor T1) is greater than the thickness of the third active layer 42 (which is the active layer thickness of the second thin-film transistor T2). The “active layer thickness” mentioned here actually refers to the thickness of the part of the active layer between source and drain electrodes.

The driving substrate 100 provided by the embodiment of the present disclosure includes a first thin-film transistor T1 and a second thin-film transistor T2 arranged on a substrate 10. The first thin-film transistor T1 includes a first gate electrode 21, a gate insulation layer 30, a first active layer 41, a second active layer 51, and first source and drain electrodes 61 stacked in sequence along a first direction X. The first source and drain electrodes 61 include a first source electrode 611 and a first drain electrode 612 spaced apart along a second direction Y. The second thin-film transistor T2 includes a second gate electrode 22, the gate insulation layer 30, a third active layer 42, a connection layer 52, and second source and drain electrodes 62 stacked in sequence along the first direction X. The second source and drain electrodes 62 includes a second source electrode 621 and a second drain electrode 622 spaced apart along a second direction Y. Herein, the connection layer 52 includes a first sub-connection 521 and a second sub-connection 522 spaced apart in the second direction Y, where the first sub-connection 521 is located between the second source electrode 621 and the third active layer 42, and the second sub-connection 522 is located between the second drain electrode 622 and the third active layer 42. Therefore, the first thin-film transistor T1 includes two active layers in parallel to achieve high mobility, while the second thin-film transistor T2 includes a single active layer. That means, the thickness of the active layer is decreased, so that the concentration of charge carriers is effectively controlled, the threshold voltage is adjustable, and off-state characteristics are improved, and thereby the stability of the device is enhanced. Therefore, the two thin-film transistors integrated in the driving substrate 100 have two characteristics, which can meet the requirements of different device characteristics in circuits.

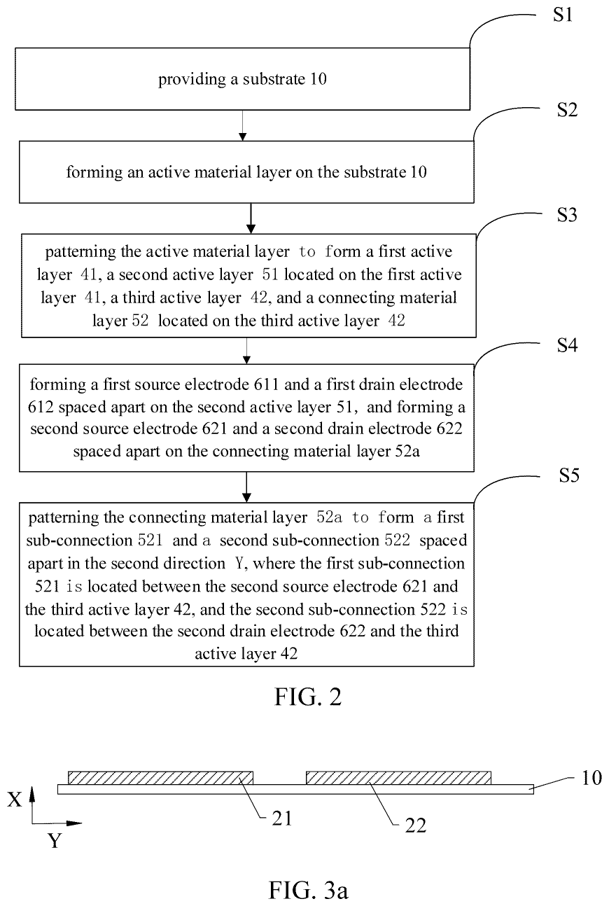

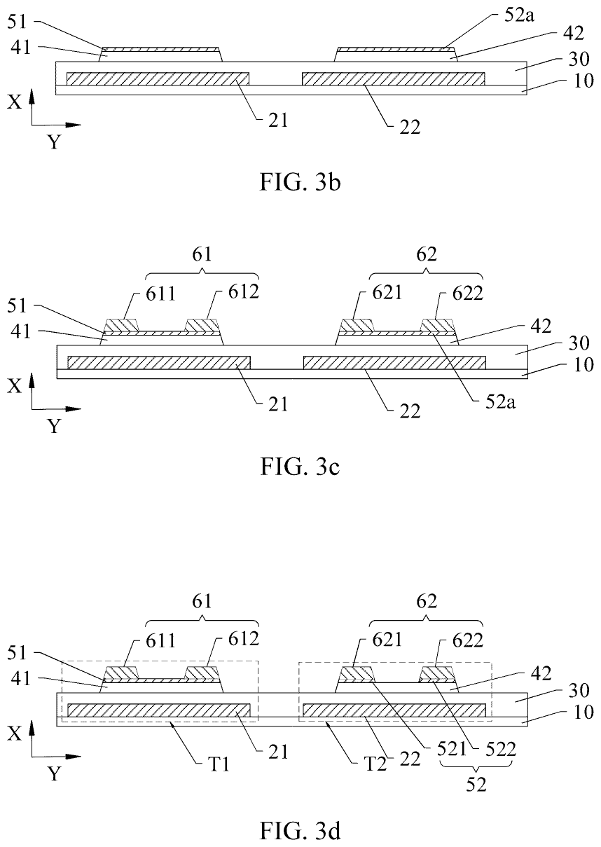

Please refer to FIG. 2, which is a schematic flow chart of a preparation method for a driving substrate according to some embodiments of the present disclosure. Please refer to FIGS. 3a-3d at the same time, FIGS. 3a to 3d are schematic diagrams of a structure of a driving substrate during preparation according to some embodiments of the present disclosure. This embodiment takes the preparation of the above-mentioned driving substrate 100 as an example to illustrate the preparation method of the driving substrate. Therefore, in combination with FIG. 1, the preparation method of the driving substrate includes the following steps S1-S5.

S1, providing a substrate 10.

S2, forming an active material layer on the substrate 10.

As shown in FIG. 3a, a mask is used to simultaneously form a first gate electrode 21 and a second gate electrode 22. Specifically, the gate electrode film is first formed by physical vapor deposition-magnetron sputtering (PVD), and then the patterns of the first gate electrode 21 and the second gate electrode 22 are formed through yellow light, wet etching, and photoresist stripping processes. Then a gate insulation layer 30 covering the first gate electrode 21 and the second gate electrode 22 is formed, and then an active material layer is formed on the gate insulation layer 30.

S3, patterning the active material layer to form a first active layer 41, a second active layer 51 located on the first active layer 41, a third active layer 42, and a connecting material layer 52 located on the third active layer 42.

As shown in FIG. 3b, two active material layers are formed successively through physical vapor deposition co-sputtering, and then annealed, and the first active material layer and the second active material layer are formed through yellow light, wet etching and photoresist stripping processes. The first active material layer includes a first active layer 41 and a second active layer 51 located on the first active layer 41, and the second active material layer includes a third active layer 42 and a connecting material layer 52a which is located on the third active layer 42.

S4, forming a first source electrode 611 and a first drain electrode 612 spaced apart on the second active layer 51, and forming a second source electrode 621 and a second drain electrode 622 spaced apart on the connecting material layer 52a.

S5, patterning the connecting material layer 52a to form a first sub-connection 521 and a second sub-connection 522 spaced apart in the second direction Y, where the first sub-connection 521 is located between the second source electrode 621 and the third active layer 42, and the second sub-connection 522 is located between the second drain electrode 622 and the third active layer 42.

Specifically, a metal layer covering the first active material layer and the second active material layer is formed, and a half-tone mask to perform a first patterning process and a second patterning process is used. Herein, the first patterning process forms a first source electrode 611 and a first drain electrode 612 located on both sides of the second active layer 51 along a second direction Y, as well as forms a second source electrode 621 and a second drain electrode 622 located on both sides of the connection layer 52 along the second direction Y. The second patterning process forms an opening in the connection layer 52 between the second source electrode 621 and the second drain electrode 622, resulting in a first sub-connection 521 and a second sub-connection 522 that are spaced apart in the second direction Y.

As shown in FIG. 3c, a first patterning process is performed to form the first source electrode 611, the first drain electrode 612, the second source electrode 621 and the second drain electrode 622.

As shown in FIG. 3d, a second patterning process is performed to make the connecting material layer 52a become a connection layer 52. The connection layer 52 includes a first sub-connection 521 and a second sub-connection 522.

Herein, the first patterning process and the second patterning process can be performed using one half-tone mask, which can save the number of masks.

In some embodiments, the first patterning process and the second patterning process are wet etching. The wet etching requires controlling the concentration of the etching liquid, and controlling the etching rate and the etching time of the connecting material layer 52a. The etching liquid can be one of nitric acid, oxalic acid, phosphoric acid, nitric sulfuric acid, fluorine-free ketone acid, and fluorine-containing ketone. The etching liquids used in the two patterning processes can be the same or different.

As shown in FIG. 1, the protective layer 70 is finally formed by chemical vapor deposition (CVD). Silicon dioxide needs to be deposited first, and then annealed. The annealing can improve the interface between the protective layer 70 and an active layer. Finally, silicon nitride is deposited to complete the preparation of the protective layer 70.

The preparation method of the driving substrate provided by the embodiments of the present disclosure can use the arrangement of a half-tone mask to realize double-layer and single-layer thin-film transistor devices, among which thin-film transistors (TFT) with higher stability requirements and relatively lower off-state characteristics requirements use a multi-layer structure of an active layer, while TFTs with higher off-state characteristics and lower stability requirements use a single-layer structure of an active layer.

The description of the above embodiments is only used to help understand the technical solution and the core idea of the present disclosure. Those of ordinary skill in the art should understand that they can still modify the technical solutions recorded in the foregoing embodiments, or make equivalent substitutions for some of the technical features. And these modifications or substitutions do not make the essence of the corresponding technical solutions away from the scope of the technical solutions of the embodiments of the present disclosure.

What is claimed is:

1. A driving substrate, wherein the driving substrate comprises:
a substrate;
a first thin-film transistor comprising a first active layer, a second active layer, and first source and drain electrodes sequentially stacked along a first direction on the substrate, the first source and drain electrodes comprising a first source electrode and a first drain electrode spaced apart along a second direction, the first direction being perpendicular to the substrate; and
a second thin-film transistor comprising a third active layer, a connection layer, and second source and drain electrodes sequentially stacked along the first direction on the substrate, the second source and drain electrodes comprising a second source electrode and a second drain electrode spaced apart along the second direction, the second direction being parallel to the substrate;
wherein the connection layer comprises a first sub-connection and a second sub-connection spaced apart in the second direction, the first sub-connection is located between the second source electrode and the third active layer, and the second sub-connection is located between the second drain electrode and the third active layer.

2. The driving substrate of claim 1, wherein the first active layer and the third active layer are located on a same layer and are made of a same material, and the second active layer and the connection layer are located on a same layer and are made of a same material.

3. The driving substrate of claim 2, wherein the first active layer is made of a material including a first metal oxide doped with a rare earth element.

4. The driving substrate of claim 3, wherein the second active layer is made of a second metal oxide, and both the first metal oxide and the second metal oxide include indium gallium zinc oxide, wherein an indium content in the first metal oxide is greater than an indium content in the second metal oxide.

5. The driving substrate of claim 1, wherein an orthographic projection of a surface, away from the substrate, of the first sub-connection on the substrate is coincided with an orthographic projection of a surface, close to the substrate, of the second source electrode on the substrate; an orthographic projection of a surface, away from the substrate, of the second sub-connection on the substrate coincides with an orthographic projection of a surface, close to the substrate, of the second drain electrode on the substrate.

6. The driving substrate of claim 1, wherein a thickness of the first active layer is greater than a thickness of the second active layer.

7. The driving substrate of claim 1, wherein the driving substrate comprises a gate driving circuit, and the gate driving circuit comprises the first thin-film transistor and the second thin-film transistor.

8. The driving substrate of claim 1, wherein a mobility of the first active layer is greater than a mobility of the second active layer.

9. The driving substrate of claim 1, wherein the first thin-film transistor further comprises a first gate electrode and a gate insulation layer, the first gate electrode is located on the substrate, and the gate insulation layer is located between the first active layer and the first gate electrode;
the second thin-film transistor further comprises a second gate electrode and the gate insulation layer, the second gate electrode is located on the substrate, and the gate insulation layer is further located between the third active layer and the second gate electrode.

10. A preparation method for a driving substrate, wherein the preparation method for the driving substrate comprises:
providing a substrate;
forming an active material layer on the substrate;
patterning the active material layer to form a first active layer, a second active layer located on the first active layer, a third active layer, and a connecting material layer located on the third active layer;
forming a first source electrode and a first drain electrode spaced apart on the second active layer, and forming a second source electrode and a second drain electrode spaced apart on the connecting material layer; and
patterning the connecting material layer to form a first sub-connection and a second sub-connection spaced apart in the second direction, wherein the first sub-connection is located between the second source electrode and the third active layer, and the second sub-connection is located between the second drain electrode and the third active layer.
